(19) United States
(12) Patent Application Publication
(10) Pub. No.: US 2024/0234147 A9
(43) Pub. Date: Jul. 11, 2024

(54) FLAME DOPING METHOD

(71) Applicant: Research & Business Foundation SUNGKYUNKWAN UNIVERSITY, Suwon-si (KR)

(72) Inventors: Jung Kyu KIM, Suwon-si (KR); Won SO, Suwon-si (KR); Jae Kyum KIM, Suwon-si (KR); Eu Jin KWAK, Suwon-si (KR)

(73) Assignee: Research & Business Foundation SUNGKYUNKWAN UNIVERSITY, Suwon-si (KR)

(21) Appl. No.: 18/375,677

(22) Filed: Oct. 2, 2023

(30) Foreign Application Priority Data
Oct. 25, 2022 (KR) 10-2022-0138168

(51) Int. Cl. H01L 21/22

(52) U.S. Cl. CPC H01L 21/22; C23C 4/129

(57) ABSTRACT

One embodiment of the present invention provides a flame doping method. Specifically, the present invention provides a flame doping method, which does not significantly change crystallinity, does not damage a substrate even while applying a high temperature, is usable as a doping method suitable for mass production, is advantageous in a process difficulty and a cost compared to other doping processes (thermal diffusion and ion implantation), and has high process stability.

### CROSS REFERENCE TO RELATED APPLICATION

The present application claims priority to Korean Patent Application No. 10-2022-0138168, filed Oct. 25, 2022, the entire contents of which is incorporated herein for all purposes by this reference.

### BACKGROUND OF THE INVENTION

### Field of the Invention

The present invention relates to a flame doping method, and more specifically, to a flame doping method, which does not significantly change crystallinity, does not damage a substrate even while applying a high temperature, may be used as a doping method suitable for mass production, is advantageous in a process difficulty and a cost compared to other doping processes (thermal diffusion and ion implantation), and has high process stability.

### Description of the Related Art

A method of doping a semiconductor material with a dopant may be largely classified into two methods: thermal diffusion and ion implantation. In this case, the dopant is supplied by being formed of fine gas particles in the form of ions.

The thermal diffusion is a method of applying heat (heating a dopant at a high temperature of 1000° C.) while supplying the dopant in the form of a gas and diffusing the dopant from a surface into a crystal of a doping target material. Since the thermal diffusion has a low cost, is simple, and is a batch-type, a production volume is good, but there is a disadvantage in that a process temperature is high, it is difficult to precisely control an amount (concentration) of implanted dopant is difficult, and the dopant diffuses isotropically, thereby causing the dopant to enter unwanted portions.

The ion implantation is a method of ionizing dopant particles and then sufficiently accelerating the particles by an electric field to implant the particles into a surface of a substrate. The ion implantation has an advantage in that a high-purity ion implantation process is possible at low temperature, and a dopant concentration and depth may be adjusted accurately, and thus it is advantageous for a fine process and high integration. On the other hand, the ion implantation has a disadvantage in that a process speed is slow due to expensive and complicated equipment and low productivity and a limitation in that thermal treatment process of applying a high temperature after ion implantation is necessarily required.

Therefore, in order to solve the problems, the present inventor completed the invention of a semiconductor material doping or a metal oxide electrode production process based on a flame process in seconds to improve electrochemical and photoelectrochemical performance.

### SUMMARY OF THE INVENTION

In order to solve the problems, the present invention is directed to providing a flame doping method including providing a substrate including a material containing a dopant, coming a doping target material into contact with the substrate, and spraying a flame in a direction from a position spaced apart from an upper end portion of the doping target material to the substrate.

In order to solve the problems, the present invention is also directed to providing a semiconductor thin film doped by the flame doping method.

In order to solve the problems, the present invention is also directed to providing an electrode material doped by the flame doping method. The object of the present invention are not limited to the above-described object, and other objects that are not mentioned will be able to be clearly understood by those skilled in the art to which the present invention pertains from the following description.

In order to achieve the objects, the present invention provides a flame doping method including providing a substrate including a material containing a dopant, coming a doping target material into contact with the substrate, and spraying a flame in a direction from a position spaced apart from an upper end portion of the doping target material to the substrate.

In the embodiment of the present invention, a temperature of the flame in the spraying of the flame may exceed 800° C.

In the embodiment of the present invention, a spraying time in the spraying of the flame may be in a range of 3 to 70 seconds.

In the embodiment of the present invention, the dopant may be one or more selected from the group consisting of Sn, Ga, In, Bi, Cu, Ni, Co, Sb, Mo, Cr, Nb, and Ta.

In the embodiment of the present invention, the doping target material may be one selected from the group consisting of WO₃, α-Fe₂O₃, TiO₂, ZnO, CuO, BiVO₄, Al₂O₃, Zr₂O₃, Co₃O₄, Nb₂O₅, and V₂O₅.

In order to achieve the objects, another embodiment of the present invention provides a semiconductor thin film doped by the flame doping method.

In order to achieve the objects, another embodiment of the present invention provides an electrode material doped by the flame doping method.

### BRIEF DESCRIPTION OF THE DRAWINGS

FIG. 1 is a view illustrating images schematizing a process of doping an Sn (metal ion derived from the substrate) flame tungsten trioxide electrode according to one embodiment of the present invention.

FIG. 2A is a view illustrating scanning electron microscope (SEM) images observing upper portions of the tungsten trioxide electrodes according to one embodiment of the present invention.

FIG. 2B is a view illustrating scanning electron microscope (SEM) images observing upper portions of the tungsten trioxide electrodes according to one embodiment of the present invention.

FIG. 2C is a view illustrating scanning electron microscope (SEM) images observing upper portions of the tungsten trioxide electrodes according to one embodiment of the present invention.

FIG. 2D is a view illustrating scanning electron microscope (SEM) images observing side surfaces of the tungsten trioxide electrodes according to one embodiment of the present invention.

FIG. 2E is a view illustrating scanning electron microscope (SEM) images observing side surfaces of the tungsten trioxide electrodes according to one embodiment of the present invention.

FIG. 2F is a view illustrating scanning electron microscope (SEM) images observing side surfaces of the tungsten trioxide electrodes according to one embodiment of the present invention.

FIG. 3A is a view illustrating transmission electron microscopy (TEM) low-magnification images observing lattice structures of the tungsten trioxide electrodes according to one embodiment of the present invention.

FIG. 3B is a view illustrating transmission electron microscopy (TEM) low-magnification images observing lattice structures of the tungsten trioxide electrodes according to one embodiment of the present invention.

FIG. 3C is a view illustrating transmission electron microscopy (TEM) low-magnification images observing lattice structures of the tungsten trioxide electrodes according to one embodiment of the present invention.

FIG. 3D is a view illustrating transmission electron microscopy (TEM) high-magnification images observing lattice structures of the tungsten trioxide electrodes according to one embodiment of the present invention.

FIG. 3E is a view illustrating transmission electron microscopy (TEM) high-magnification images observing lattice structures of the tungsten trioxide electrodes according to one embodiment of the present invention.

FIG. 3F is a view illustrating transmission electron microscopy (TEM) high-magnification images observing lattice structures of the tungsten trioxide electrodes according to one embodiment of the present invention.

FIG. 4A is a view illustrating a result of analyzing energy dispersive spectrometer (EDS) line profiles on the side surfaces of the bare tungsten trioxide electrode.

FIG. 4B is a view illustrating a result of analyzing energy dispersive spectrometer (EDS) line profiles on the side surfaces of the tungsten trioxide electrode on which the Sn flame doping has been performed.

FIG. 4C is a view illustrating a result of analyzing energy dispersive spectrometer (EDS) line profiles on the side surfaces of the tungsten trioxide electrode on which the Sn furnace doping has been performed.

FIG. 5 is a view illustrating an X-ray diffraction (XRD) pattern result for checking the crystallinity of the tungsten trioxide electrodes according to one embodiment of the present invention.

FIG. 6A is a view illustrating an X-ray photoelectron spectroscopy (XPS) spectra result for checking a result of analyzing components and atomic bond states of the tungsten trioxide electrodes according to one embodiment of the present invention, which is possible to check XPS spectra for C is of the tungsten trioxide electrodes.

FIG. 6B is a view illustrating an X-ray photoelectron spectroscopy (XPS) spectra result for checking a result of analyzing components and atomic bond states of the tungsten trioxide electrodes according to one embodiment of the present invention, which is possible to check XPS spectra for 0 is of the tungsten trioxide electrodes.

FIG. 6C is a view illustrating an X-ray photoelectron spectroscopy (XPS) spectra result for checking a result of analyzing components and atomic bond states of the tungsten trioxide electrodes according to one embodiment of the present invention, which is possible to check XPS spectra for W4f of the tungsten trioxide electrodes.

FIG. 6D is a view illustrating an X-ray photoelectron spectroscopy (XPS) spectra result for checking a result of analyzing components and atomic bond states of the tungsten trioxide electrodes according to one embodiment of the present invention, which is possible to check XPS spectra for Sn 3d of the tungsten trioxide electrodes.

FIG. 7A is a view illustrating a voltage-current density graph within a 0.1 M KPi buffer solution and a hole scavenger electrolyte for checking the photoelectrochemical performance of the bare tungsten trioxide electrode.

FIG. 7B is a view illustrating a voltage-current density graph within a 0.1 M KPi buffer solution and a hole scavenger electrolyte for checking the photoelectrochemical performance of the tungsten trioxide electrode on which the Sn flame doping has been performed.

FIG. 7C is a view illustrating a voltage-current density graph within a 0.1 M KPi buffer solution and a hole scavenger electrolyte for checking the photoelectrochemical performance of the tungsten trioxide electrode on which the Sn furnace doping has been performed.

FIG. 8A is a view illustrating a result of measurement analysis for checking the optical properties of the tungsten trioxide electrodes according to one embodiment of the present invention, which illustrates a result of measuring diffuse reflectance of the tungsten trioxide electrodes.

FIG. 8B is a view illustrating a result of measurement analysis for checking the optical properties of the tungsten trioxide electrodes according to one embodiment of the present invention, which illustrates a result of measuring diffuse transmittance of the tungsten trioxide electrodes.

FIG. 8C is a view illustrating a result of measurement analysis for checking the optical properties of the tungsten trioxide electrodes according to one embodiment of the present invention, which illustrates a result of measuring light absorptance of the tungsten trioxide electrodes.

FIG. 8D is a view illustrating a result of measurement analysis for checking the optical properties of the tungsten trioxide electrodes according to one embodiment of the present invention, which illustrates a result of measuring light absorbance of the tungsten trioxide electrodes.

FIG. 9A is a view illustrating a result of measuring optical haze of the bare tungsten trioxide electrodes.

FIG. 9B is a view illustrating a result of measuring optical haze of the tungsten trioxide electrode on which the Sn flame doping has been performed.

FIG. 9C is a view illustrating a result of measuring optical haze of the tungsten trioxide electrode on which the Sn furnace doping has been performed.

### DETAILED DESCRIPTION OF THE INVENTION

Hereinafter, the present invention will be described with reference to the accompanying drawings. However, the present invention may be implemented in various different forms and is not limited to embodiments described herein. In addition, in order to clearly describe the present invention in the drawings, components irrelevant to the description have been omitted, and throughout the specification, similar components have been denoted by similar reference numerals.

Throughout the specification, when a first component is described as being “connected to (joined to, in contact with, or coupled to)” a second component, this includes not only a case in which the first component is “directly connected” to the second component, but also a case in which the first component is “indirectly connected” to the second component with a third component interposed therebetween. In addition, when the first component is described as “including,” the second component, this means that the first component may further include the third component rather than precluding the third component unless especially stated otherwise. In addition, “parts by mole” is the relative number of moles of other constituent materials to the number of moles of one reference material. In this case, the reference material may be one of the constituent materials.

The terms used in the specification are only used to describe specific embodiments and are not intended to limit the present invention. The singular expression includes the plural expression unless the context clearly dictates otherwise. In the specification, it should be understood that terms such as “comprise” or “have” are intended to specify that a feature, a number, a step, an operation, a component, a part, or a combination thereof described in the specification is present, but do not preclude the possibility of the presence or addition of one or more other features, numbers, steps, operations, components, parts, or combinations thereof.

Hereinafter, embodiments of the present invention will be described in detail with reference to the accompanying drawings.

In order to achieve the objects, one embodiment of the present invention provides a flame doping method including providing a substrate including a material containing a dopant, coming a doping target material into contact with the substrate, and spraying a flame in a direction from a position spaced apart from an upper end portion of the doping target material to the substrate.

Since the spraying of the flame uses a flame at a temperature of 15 to 40° C. and a normal pressure, it is possible to resolve all weaknesses of conventional semiconductor thin film and metal oxide doping processes and at the same time, reduce unit costs. In addition, since metal ions of a substrate under a doping target material are doped within a short time through thermal diffusion, it is possible to prevent damage to the metal oxide and the substrate vulnerable to a thermal impact and also make a subsequent cutting processing on the electrode manufactured by being doped by the flame doping method possible.

In addition, the doping reaction may be designed under the oxidizing or reducing condition by adjusting the gas atmosphere under the normal pressure condition, thereby enabling the effective control of doping variables.

In addition, by using the flame doping method, the doping of the metal ions having a large atomic radius may be possible with little change in the physical properties and crystallinity of the conventional material while applying a high temperature flame in seconds within a short time. In particular, although the flame doping method is a post-treatment doping process, it is advantageous in the process difficulty and the cost compared to other doping processes, and the process stability may be high.

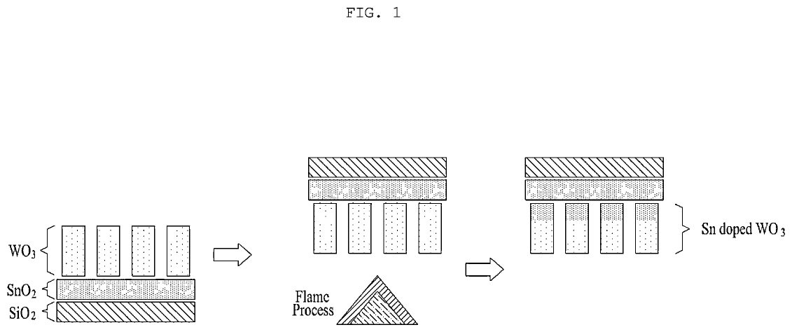

FIG. 1 is a view illustrating images schematizing a process of doping an Sn (metal ion derived from the substrate) flame tungsten trioxide electrode according to one embodiment of the present invention.

Referring to FIG. 1, the tungsten trioxide electrode having an Sn ion concentration gradient may be finally obtained by doping the Sn metal ions derived from the substrate into the trioxide electrode through the flame process for the tungsten trioxide electrode synthesized by a hydrothermal synthesis method.

In the embodiment of the present invention, a temperature of the flame in the spraying of the flame may be characterized by exceeding 800° C. The temperature of the flame in the spraying of the flame may preferably exceed 800° C., more preferably, may be 850° C. or higher, 900° C. or higher, or 950° C. or higher, and most preferably, 1000° C. or higher.

In the embodiment of the present invention, a spraying time in the spraying of the flame may be characterized by being in a range of 3 to 70 seconds. The spraying time in the spraying of the flame may be preferably in a range of 3 to 70 seconds, more preferably, in a range of 5 to 65 seconds, 10 to 60 seconds, 15 to 55 seconds, or 20 to 50 seconds, and most preferably, in a range of 30 to 50 seconds.

In the embodiment of the present invention, the dopant may be one or more selected from the group consisting of Sn, Ga, In, Bi, Cu, Ni, Co, Sb, Mo, Cr, Nb, and Ta.

In the embodiment of the present invention, the doping target material may be one selected from the group consisting of WO₃, α-Fe₂O₃, TiO₂, ZnO, CuO, BiVO₄, Al₂O₃, Zr₂O₃, Co₃O₄, Nb₂O₅, and V₂O₅.

In order to achieve the objects, another embodiment of the present invention provides a semiconductor thin film doped by the flame doping method.

In order to achieve the objects, another embodiment of the present invention provides an electrode material doped by the flame doping method.

Hereinafter, the above-described embodiment will be described in more detail through examples or experimental examples. However, the following examples or experimental examples are only for the purpose of description and do not limit the scope.

### Example

The manufactured Sn flame doping tungsten trioxide electrode may be manufactured by the following synthesis and doping methods.

### Example 1—Synthesis of Tungsten Trioxide Seed Layer

(1) put 0.375 g of H₂WO₄ into 3 mL of H₂O₂ (30%) and stir the solution at 140° C. for 6 hours.

(2) put 9 mL of DI aqueous solution and 0.15 g of polyvinyl alcohol (PVA) into the solution in (1) and stir the solution at 70° C. at 500 rpm for 10 minutes and then at 1100 rpm for 15 minutes.

(3) perform aging treatment on the solution in (2) at room temperature for 1 day.

(4) filter the solution in (3) with a hydrophilic filter, and then spin-coat 210 μL onto 15 ohm fluorine-doped tin oxide (FTO) (at 2000 rpm for 30 seconds).

(5) dry the FTO coated in (4) on a hot plate at 110° C. for 20 minutes, and then perform thermal treatment in a furnace at 500° C. for 2 hours.

### Example 2—Hydrothermal Synthesis of Tungsten Trioxide Electrode Having Two-Dimensional (2D) Nanosheet Structure

(1) put 0.179 g of H₂WO₄ and 3.57 mL of DI aqueous solution into 2.43 mL of H₂O₂ (30%).

(2) stir the solution in (1) at 100° C. for 15 minutes.

(3) put 14.84 mL of acetonitrile, 0.59 mL of HCl (6M), 0.059 g of Urea, and 0.024 g of oxalic acid into 3.56 mL of the solution in (2) and stir the solution for 10 minutes.

(4) put the solution of (3) in a PTFE autoclave together with the FTO on which the seed layer on which the process of Example 1 (5) was completed was deposited and perform a reactor in an oil bath at 180° C. for 2 hours.

(5) after 2 hours, cool the reactor in (4) before taking out the FTO in which the tungsten trioxide was synthesized. Then, the FTO in which the internal tungsten trioxide was synthesized is dried at 110° C. for 20 minutes, and then thermally treated in the furnace at 500° C. for 2 hours. After finishing the corresponding process, the tungsten trioxide electrode having the 2D nanosheet structure may be obtained.

### Example 3—Flame Doping

(1) the tungsten trioxide electrode obtained in (5) in Example 2 was thermally treated at 1000° C. for 40 seconds using flame equipment. Then, the corresponding sample was cooled in the upper flame for 30 seconds and finally cooled in the air.

### Comparative Example 1—Furnace Doping

(1) The tungsten trioxide electrode obtained in (5) in Example 2 was thermally treated in the furnace at 500° C. for 30 minutes.

### Experimental Example

1. SEM and TEM Analyses and Results

SEM images and TEM images were obtained by using a SEM instrument (FE-SEM, JSM-7600F) and a TEM instrument (HRTEM, JEOL JEM-2000).

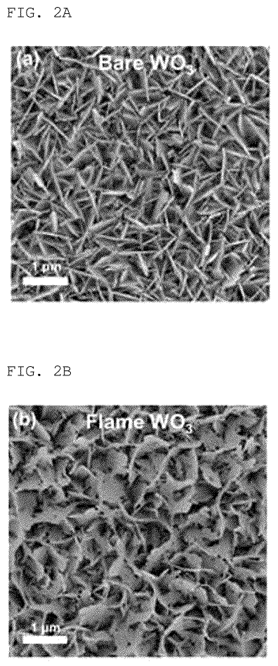

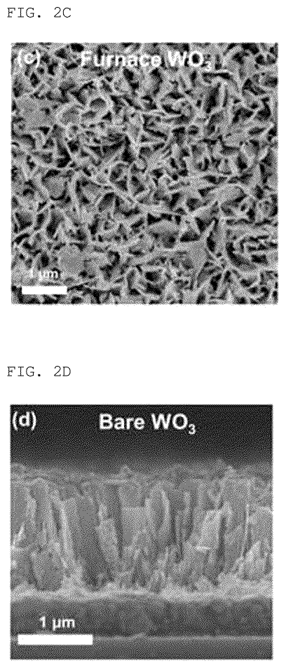

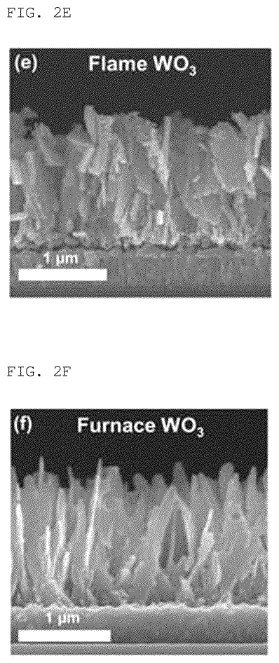

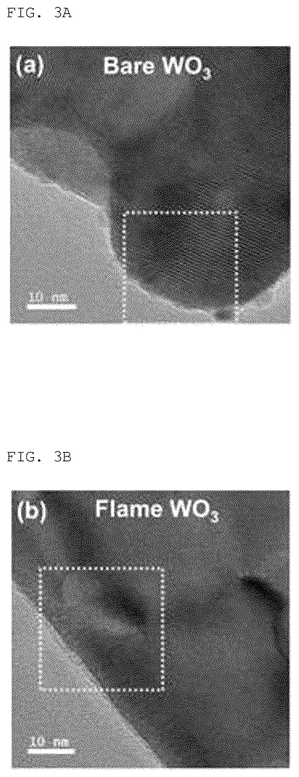

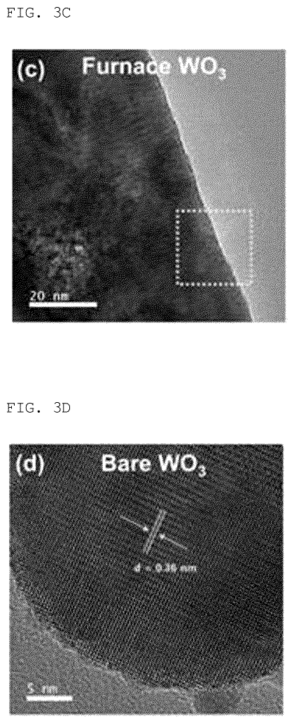

FIGS. 2A to 2F are views illustrating scanning electron microscope (SEM) images observing upper portions and side surfaces of the tungsten trioxide electrodes according to one embodiment of the present invention. Specifically, FIGS. 2A to 2C are views illustrating the SEM images observing the upper portion of the tungsten trioxide electrode [FIG. 2A illustrates a bare tungsten trioxide electrode, FIG. 2B illustrates a tungsten trioxide electrode on which Sn flame doping has been performed, and FIG. 2C illustrates a tungsten trioxide electrode on which Sn furnace doping has been performed], and FIGS. 2D to 2F are views illustrating SEM images observing the side surfaces of the tungsten trioxide electrode [FIG. 2D illustrates the bare tungsten trioxide electrode, FIG. 2E illustrates the tungsten trioxide electrode on which the Sn flame doping has been performed, and FIG. 2F illustrates the tungsten trioxide electrode on which the Sn furnace doping has been performed].

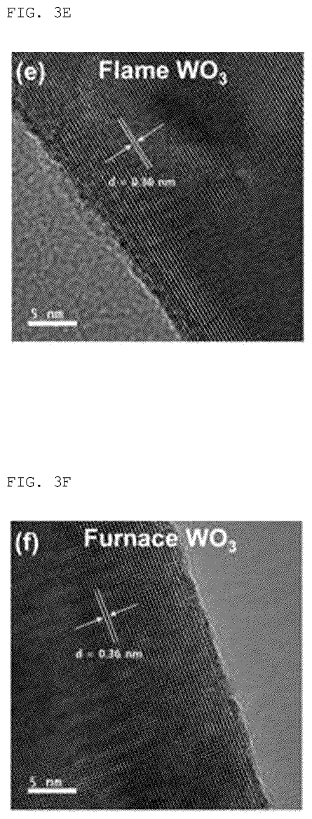

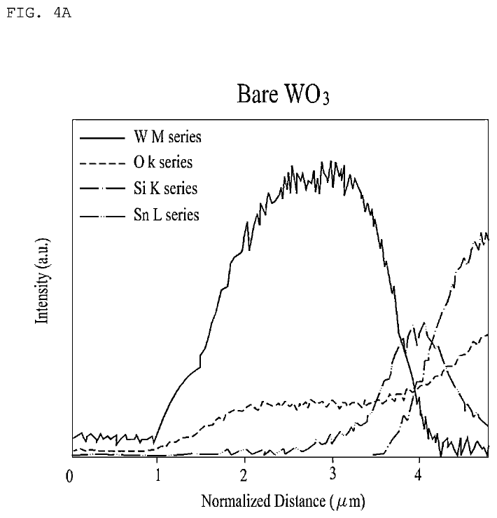

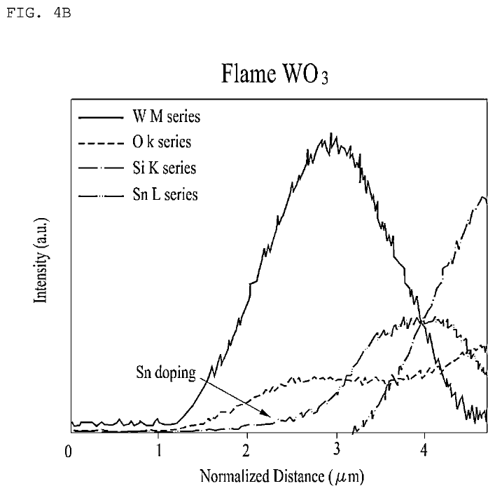

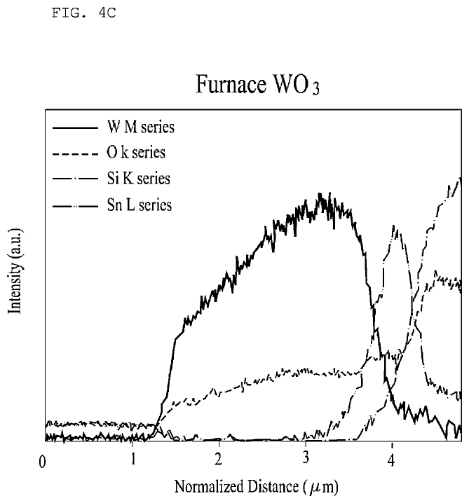

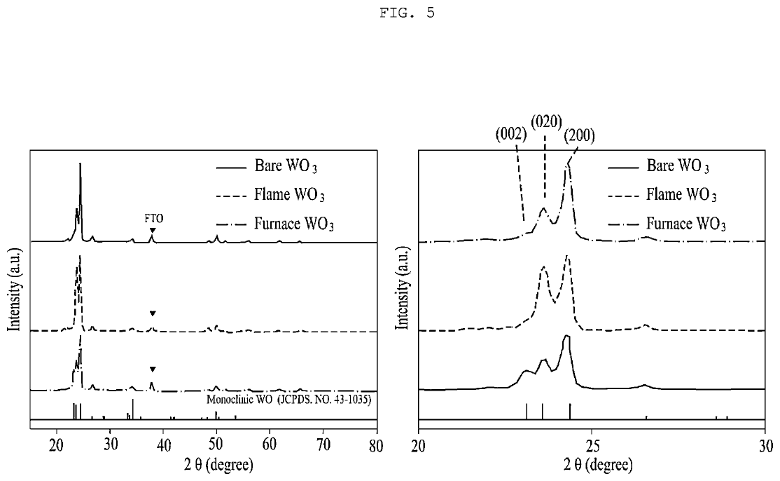

FIGS. 3A to 3F are views illustrating transmission electron microscopy (TEM) images observing lattice structures of the tungsten trioxide electrodes according to one embodiment of the present invention. Specifically, FIGS. 3A to 3C are views illustrating the TEM low-magnification images observing the tungsten trioxide electrode [FIG. 3A illustrates the bare tungsten trioxide electrode, FIG. 3B illustrates the tungsten trioxide electrode on which the Sn flame doping has been performed, and FIG. 3C illustrates the tungsten trioxide electrode on which the Sn furnace doping has been performed], and FIGS. 3D to 3F are views illustrating TEM high-magnification images observing the tungsten trioxide electrode [FIG. 3D illustrates the bare tungsten trioxide electrode, FIG. 3E illustrates the tungsten trioxide electrode on which the Sn flame doping has been performed, and FIG. 3F illustrates the tungsten trioxide electrode on which the Sn furnace doping has been performed].

Referring to FIGS. 2A to 2F and 3A to 3F, it can be seen that there is no difference in a surface morphology and a lattice structure of the tungsten trioxide due to the flame doping treatment compared to before doping.

2. Line Profile Analysis in SEM and Result

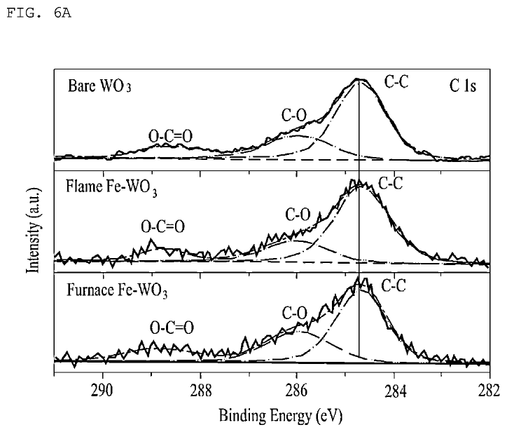

FIGS. 4A to 4C are views illustrating a result of analyzing energy dispersive spectrometer (EDS) line profiles on the side surfaces of the tungsten trioxide electrodes according to one embodiment of the present invention. [FIG. 4A illustrates the bare tungsten trioxide electrode, FIG. 4B illustrates the tungsten trioxide electrode on which the Sn flame doping has been performed, and FIG. 4C illustrates the tungsten trioxide electrode on which the Sn furnace doping has been performed]

Referring to FIGS. 4A to 4C, it can be seen that a degree of the Sn doping of the tungsten trioxide electrode on which the Sn flame doping was performed was the largest, and it can be seen that a concentration gradient for the Sn metal ions was observed in the electrode using the flame doping method, and Sn was well doped inside the tungsten trioxide.

3. XRD Analysis and Result

XRD images were obtained by using an XRD instrument (D8 ADVANCE with Cu Kα radiation).

FIG. 5 is a view illustrating an X-ray diffraction (XRD) pattern result for checking the crystallinity of the tungsten trioxide electrodes according to one embodiment of the present invention.

Referring to FIG. 5, when compared to a peak of a JCPDS card of monoclinic tungsten trioxide, it can be seen that positions of each peak match with each other, and it can be seen that when the Sn flame doping treatment was performed, a size of a peak corresponding to a (020) plane of the tungsten trioxide increased.

4. XPS Analysis and Result

XPS images were obtained by using an XPS instrument (ESCALAB250).

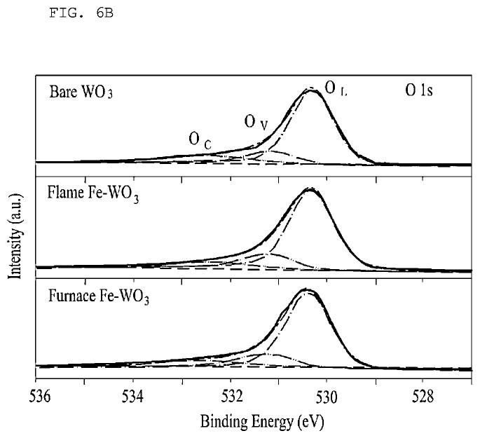

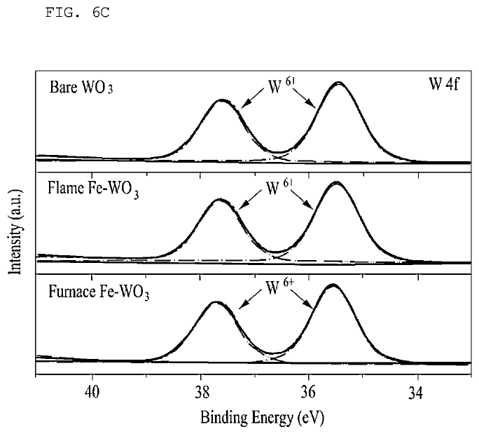

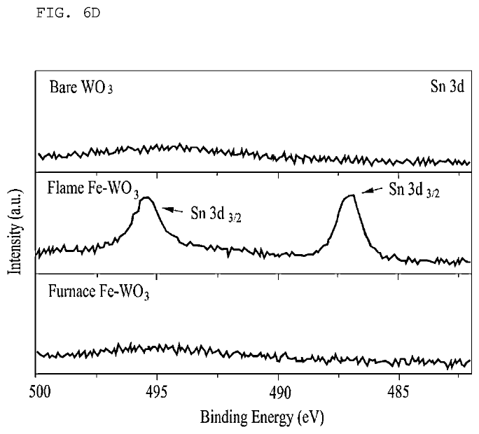

FIG. 6A is a view illustrating an X-ray photoelectron spectroscopy (XPS) spectra result for checking a result of analyzing components and atomic bond states of the tungsten trioxide electrodes according to one embodiment of the present invention, which is possible to check XPS spectra for C is of the tungsten trioxide electrodes.

FIG. 6B is a view illustrating an X-ray photoelectron spectroscopy (XPS) spectra result for checking a result of analyzing components and atomic bond states of the tungsten trioxide electrodes according to one embodiment of the present invention, which is possible to check XPS spectra for O 1s of the tungsten trioxide electrodes.

FIG. 6C is a view illustrating an X-ray photoelectron spectroscopy (XPS) spectra result for checking a result of analyzing components and atomic bond states of the tungsten trioxide electrodes according to one embodiment of the present invention, which is possible to check XPS spectra for W 4f of the tungsten trioxide electrodes.

FIG. 6D is a view illustrating an X-ray photoelectron spectroscopy (XPS) spectra result for checking a result of analyzing components and atomic bond states of the tungsten trioxide electrodes according to one embodiment of the present invention, which is possible to check XPS spectra for Sn 3d of the tungsten trioxide electrodes.

5. Result of Measuring Photoelectrochemical Performance

Photoelectrochemical performance (PEC) analysis images were obtained by using a CHI instrument (Gamry 600+workstation). The analysis was performed by a three-electrode system in 1 M KPi buffer solution (pH 7.0).

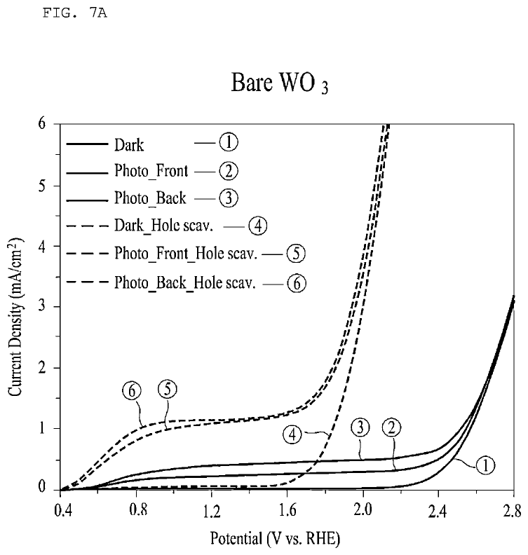

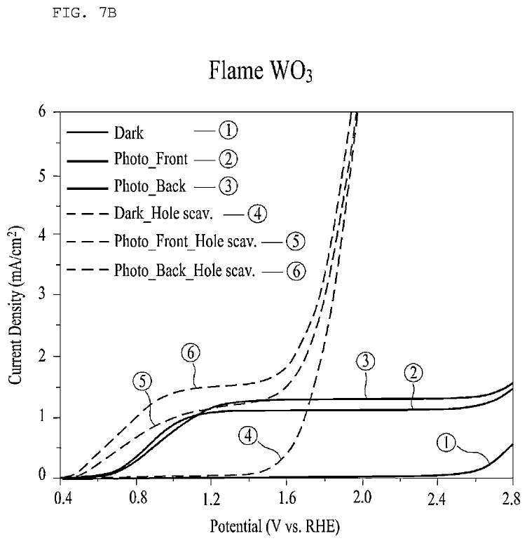

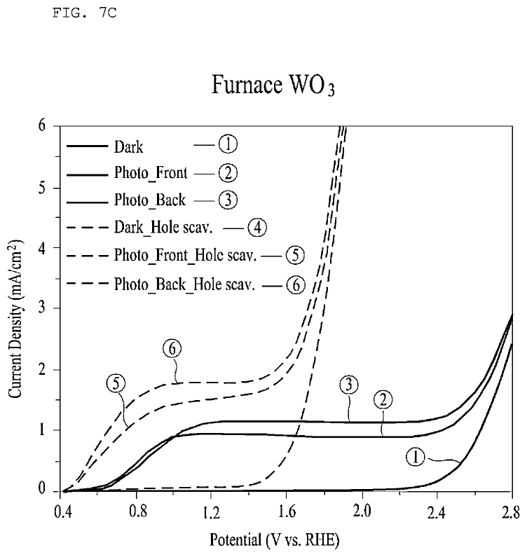

FIGS. 7A to 7C are views illustrating a voltage-current density graph within a 0.1 M KPi buffer solution and a hole scavenger electrolyte for checking the PEC of the tungsten trioxide electrodes according to one embodiment of the present invention. Specifically, FIG. 7A illustrates the bare tungsten trioxide electrode, FIG. 7B illustrates the tungsten trioxide electrode on which the Sn flame doping has been performed, and FIG. 7C illustrates the tungsten trioxide electrode on which the Sn furnace doping has been performed.

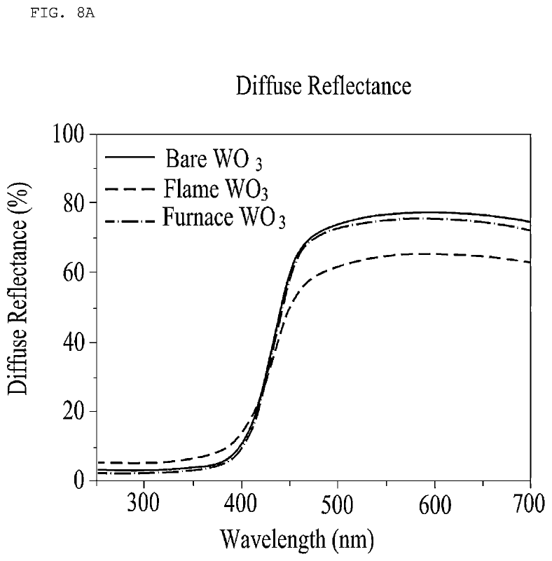

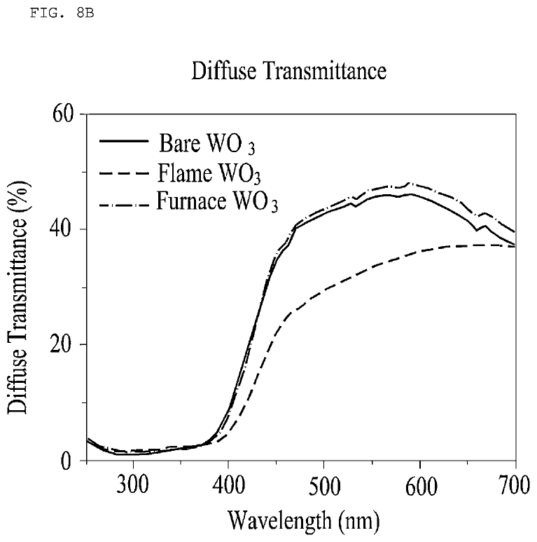

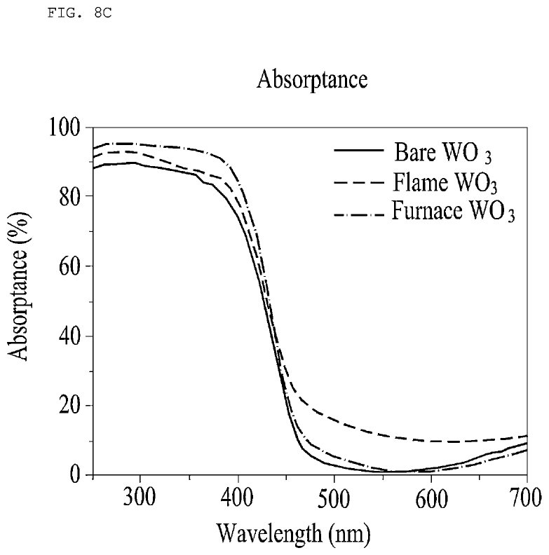

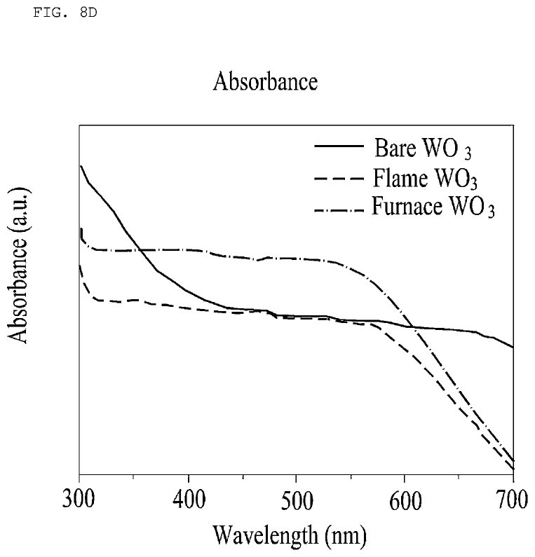

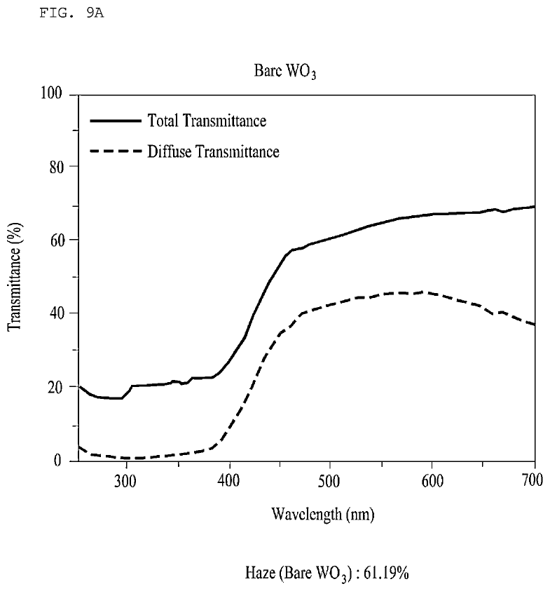

FIGS. 8A to 8D are views illustrating a result of measurement analysis for checking the optical properties of the tungsten trioxide electrodes according to one embodiment of the present invention. Specifically, FIG. 8A illustrates a result of measuring diffuse reflectance of the tungsten trioxide electrodes, FIG. 8B illustrates a result of measuring diffuse transmittance of the tungsten trioxide electrodes, FIG. 8C illustrates a result of measuring light absorptance of the tungsten trioxide electrodes, and FIG. 8D illustrates a result of measuring light absorbance of the tungsten trioxide electrodes.

Referring to FIGS. 7A to 7C and 8A to 8D, in PEC graphs of the tungsten trioxide electrodes when irradiated with light, performance in the tungsten trioxide sample on which the flame doping treatment was performed was measured to be the highest. In addition, it can be seen that charge transfer efficiency was improved due to doping.

6. Result of Analyzing UV-Vis Spectra

XRD images were obtained by using an UV-Vis spectra instrument (SHIMADZU UV-3600i plus).

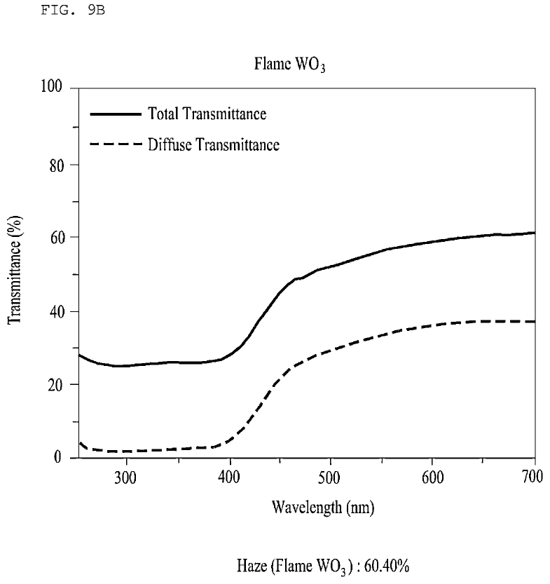

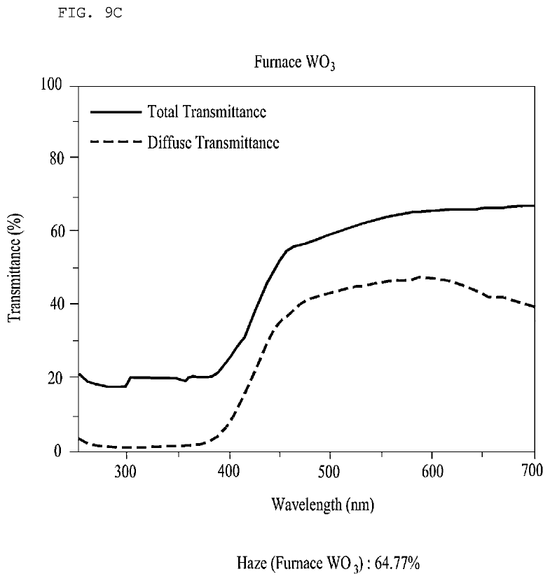

FIGS. 9A to 9C are views illustrating a result of measuring optical haze of the tungsten trioxide electrodes according to one embodiment of the present invention. [FIG. 9A illustrates the bare tungsten trioxide electrode, FIG. 9B illustrates the tungsten trioxide electrode on which the Sn flame doping has been performed, and FIG. 9C illustrates the tungsten trioxide electrode on which the Sn furnace doping has been performed]

Referring to FIGS. 9A to 9C, a light absorption rate of the electrode using the flame doping method increased in a long wavelength band. In addition, it can be seen that an optical haze value of the electrode was also increased when the flame doping method was used.

The above description of the present invention is for illustrative purpose, and those skilled in the art to which the present invention pertains will be able to understand that the present invention may be easily modified in other specific forms without changing the technical spirit or essential features thereof. Therefore, it should be understood that the above-described embodiments are illustrative and not restrictive in all respects. For example, each component described in a singular form may be implemented separately, and likewise, components described as being implemented separately may also be implemented in a combined form.

According to the embodiment of the present invention, the flame doping method may perform the doping of metal ions having a large atomic radius with little change in physical properties and crystallinity of the conventional material while applying a short and high-temperature thermal treatment in seconds.

In addition, the process difficulty and the cost are advantageous compared to other doping processes, and the process stability is high.

In addition, the doping reaction may be designed under the oxidizing or reducing condition by adjusting the gas atmosphere under the normal pressure condition, thereby enabling the effective control of doping variables.

The flame doping method and a method of manufacturing an electrode using the same are very encouraging techniques in relation to the manufacture of semiconductors and metal oxide thin films and may function to solve problems such as a production cost, process stability, and the like.

The manufactured electrode may be applied as an important high-efficiency electrode in green hydrogen production and energy conversion sectors.

In addition, the flame doping method may be introduced as a doping method not only in the manufacture of high-efficiency metal oxide electrodes, but also in various semiconductors such as system semiconductors and nano devices, amorphous solar energy, transparent conducting oxide (TCO), and a coating glass production technology.

Since an electrode manufactured by being doped by the flame doping method is doped with metal ions of a substrate under the material within a short time through thermal diffusion, it is possible to prevent damage to metal oxide and the substrate vulnerable to a thermal impact and make subsequent cutting processing possible by not causing thermal strengthening of the substrate itself.

The electrode manufactured by the invention may have improved light harvesting characteristics and electrochemical properties and effectively convert light energy into electrochemical energy. Therefore, the manufactured photoelectrode with improved electrochemical properties may be applied to the high-efficiency solar-to-hydrogen (STH) photoelectrode system to contribute to performance improvement.

It should be understood that the effects of the present invention are not limited to the above-described effects and include all effects inferrable from the configuration of the invention described in the detailed description or claims of the present invention.

The scope of the present invention is defined by the claims to be described below, and all changes or modifications derived from the meaning and scope of the claims and equivalent concepts thereof should be construed as being included in the scope of the present invention.

What is claimed is:

1. A flame doping method comprising:
providing a substrate including a material including a dopant;
coming a doping target material into contact with the substrate; and
spraying a flame in a direction from a position spaced apart from an upper end portion of the doping target material to the substrate.

2. The flame doping method according to claim 1, wherein a temperature of the flame in the spraying of the flame exceeds 800° C.

3. The flame doping method according to claim 1, wherein a spraying time in the spraying of the flame is in a range of 3 to 70 seconds.

4. The flame doping method according to claim 1, wherein the dopant is one or more selected from the group consisting of Sn, Ga, In, Bi, Cu, Ni, Co, Sb, Mo, Cr, Nb, and Ta.

5. The flame doping method according to claim 1, wherein the doping target material is one selected from the group consisting of WO₃, α-Fe₂O₃, TiO₂, ZnO, CuO, BiVO₄, Al₂O₃, Zr₂O₃, Co₃O₄, Nb₂O₅, and V₂O₅.

6. A semiconductor thin film doped by the flame doping method of claim 1.

7. An electrode material doped by the flame doping method of claim 1.
